(19) United States
(12) Patent Application Publication
(10) Pub. No.: US 2024/0093359 A1
(43) Pub. Date: Mar. 21, 2024

(54) Fixtures for Chemical Vapor Deposition Gradient Coatings

(71) Applicant: HZO, Inc., Morrisville, NC (US)

(72) Inventors: Sean Clancy, Apex, NC (US); James Tosh, Morrisville, NC (US)

(21) Appl. No.: 18/468,680

(22) Filed: Sep. 15, 2023

Related U.S. Application Data
(60) Provisional application No. 63/406,883, filed on Sep. 15, 2022.

(51) Int. Cl. C23C 16/04

(52) U.S. Cl. CPC C23C 16/04

(57) ABSTRACT

A fixture for depositing a gradient coating includes a single opening on a front side of the fixture, such that the fixture is configured to house a substrate during deposition of a coating and configured to surround the substrate on all sides of the substrate except for a single front side of the substrate, and wherein the fixture is configured to restrict egress of coating material to the substrate from all directions except through the single opening. The fixture includes a cavity such that the fixture is configured to leave an air gap between a lid surface of the fixture and the major top side of the substrate, and a cavity depth, measured from the front side of the fixture to a back of the cavity, is greater than a gap opening distance, measured from the lid surface at the opening to the major top side of the substrate.

### RELATED APPLICATIONS

This application claims the benefit of U.S. Provisional Patent Application No. 63/406,883, filed Sep. 15, 2022, which is incorporated herein by reference in its entirety

### BACKGROUND

This disclosure relates generally to fixtures for chemical vapor deposition gradient coatings.

Chemical vapor deposition (CVD) coatings, such as the Parylenes, have various levels of “crevice penetration”, “penetration depth”, or “throwing distance” defined by the material [chemical structure of the coating's reactive monomer, that monomer's sticking coefficient, etc.], the process parameters [deposition rate, base pressure, chamber temperature, target thickness, etc.], and substrate [aperture or opening size into the area to be coated, the internal volume and geometry of the area to be coating, etc.].

Taking the coating material and deposition process into account, then well-defined and controlled apertures and internal volumes have provided the desired coating gradients for applications related to a variety of engineering and scientific applications, such as optical spectroscopy.

Fixtures have been developed to provide controlled thickness gradients over defined areas, such as silicon wafers, for single- and double-sided coating applications.

### SUMMARY

The subject matter of the present application has been developed in response to the present state of the art, and in particular, in response to the problems and disadvantages associated with conventional deposition systems that have not yet been fully solved by currently available techniques. Accordingly, the subject matter of the present application has been developed to provide embodiments of a chemical vapor deposition gradient coating system and fixture that overcome at least some of the shortcomings of prior art techniques.

Disclosed herein is a fixture for depositing a gradient coating includes a single opening on a front side of the fixture, such that the fixture is configured to house a substrate during deposition of a coating and configured to surround the substrate on all sides of the substrate except for a single front side of the substrate, and wherein the fixture is configured to restrict egress of coating material to the substrate from all directions except through the single opening. The fixture includes a cavity such that the fixture is configured to leave an air gap between a lid surface of the fixture and the major top side of the substrate, and a cavity depth, measured from the front side of the fixture to a back of the cavity, is greater than a gap opening distance, measured from the lid surface at the opening to the major top side of the substrate. The preceding subject matter of this paragraph characterizes example 1 of the present disclosure.

The lid surface is contoured to match a shape of the major top surface. The preceding subject matter of this paragraph characterizes example 2 of the present disclosure, wherein example 2 also includes the subject matter according to example 1, above.

The substrate comprises a gradient coating with a first thickness at the opening and a second thickness at a rear of the cavity, wherein the first thickness is greater than the second thickness. The preceding subject matter of this paragraph characterizes example 3 of the present disclosure, wherein example 3 also includes the subject matter according to any one of examples 1-2, above.

The cavity depth is ten times greater than the gap opening distance. The preceding subject matter of this paragraph characterizes example 4 of the present disclosure, wherein example 4 also includes the subject matter according to any one of examples 1-3, above.

The cavity depth is one hundred times greater than the gap opening distance. The preceding subject matter of this paragraph characterizes example 5 of the present disclosure, wherein example 5 also includes the subject matter according to any one of examples 1-3, above.

The lid surface is graded or sloped such that a gap distance from the lid surface to the major top side decreases with depth into the cavity. The preceding subject matter of this paragraph characterizes example 6 of the present disclosure, wherein example 6 also includes the subject matter according to any one of examples 1-5, above.

The fixture is configured to leave a second air gap between a bottom lid surface of the fixture and a major bottom side of the substrate. The preceding subject matter of this paragraph characterizes example 7 of the present disclosure, wherein example 7 also includes the subject matter according to any one of examples 1-6, above.

The lid surface is contoured to match a shape of the major top surface and the bottom lid surface of the fixture is contoured to match a shape of a major bottom surface of the substrate. The preceding subject matter of this paragraph characterizes example 8 of the present disclosure, wherein example 8 also includes the subject matter according to any one of examples 1-7, above.

Disclosed herein is a chemical vapor deposition coating system for depositing a gradient coating including substrate comprising a major top side, wherein the first major top side is to be deposited with a coating of a material via chemical vapor deposition and a fixture for the substrate, the fixture configured to house the substrate during deposition of the coating fixture is configured to surround the substrate on all sides of the substrate except for a single front side of the substrate. The fixture comprises an opening on a front side of the fixture, and wherein the fixture is configured to restrict egress of the material to the substrate from all directions except through the opening and a cavity such that the fixture is configured to leave an air gap between a lid surface of the fixture and the major top side of the substrate. The fixture includes a cavity depth, measured from the front side of the fixture to a back of the cavity, is greater than a gap opening distance, measured from the lid surface at the opening to the major top side of the substrate. The preceding subject matter of this paragraph characterizes example 9 of the present disclosure.

The lid surface is contoured to match a shape of the major top surface. The preceding subject matter of this paragraph characterizes example 10 of the present disclosure, wherein example 10 also includes the subject matter according to example 9, above.

The substrate comprises a gradient coating with a first thickness at the opening and a second thickness at a rear of the cavity, wherein the first thickness is greater than the second thickness. The preceding subject matter of this paragraph characterizes example 11 of the present disclosure, wherein example 11 also includes the subject matter according to any one of examples 9-10, above.

The cavity depth is ten times greater than the gap opening distance. The preceding subject matter of this paragraph characterizes example 12 of the present disclosure, wherein example 12 also includes the subject matter according to any one of examples 9-11, above.

The cavity depth is one hundred times greater than the gap opening distance. The preceding subject matter of this paragraph characterizes example 13 of the present disclosure, wherein example 13 also includes the subject matter according to any one of examples 9-11, above.

The lid surface is graded or sloped such that a gap distance from the lid surface to the major top side decreases with depth into the cavity. The preceding subject matter of this paragraph characterizes example 14 of the present disclosure, wherein example 14 also includes the subject matter according to any one of examples 9-13, above.

The fixture is configured to leave a second air gap between a bottom lid surface of the fixture and a major bottom side of the substrate. The preceding subject matter of this paragraph characterizes example 15 of the present disclosure, wherein example 15 also includes the subject matter according to any one of examples 9-14, above.

The lid surface is contoured to match a shape of the major top surface and the bottom lid surface of the fixture is contoured to match a shape of a major bottom surface of the substrate. The preceding subject matter of this paragraph characterizes example 16 of the present disclosure, wherein example 16 also includes the subject matter according to example 15, above.

The substrate comprises a gradient coating with a first thickness at the opening and a second thickness at a rear of the cavity on the major top side, wherein the first thickness is greater than the second thickness, and wherein the substrate comprises a second gradient coating onto the major bottom side of the substrate. The preceding subject matter of this paragraph characterizes example 17 of the present disclosure, wherein example 17 also includes the subject matter according to any one of examples 15-16, above.

The cavity depth is ten times greater than the gap opening distance. The preceding subject matter of this paragraph characterizes example 18 of the present disclosure, wherein example 18 also includes the subject matter according to any one of examples 15-17, above.

The cavity depth is one hundred times greater than the gap opening distance. The preceding subject matter of this paragraph characterizes example 19 of the present disclosure, wherein example 19 also includes the subject matter according to any one of examples 15-17, above.

The lid surface stepped surface such that a gap distance from the lid surface to the major top side decreases with depth into the cavity. The preceding subject matter of this paragraph characterizes example 20 of the present disclosure, wherein example 20 also includes the subject matter according to any one of examples 15-19, above.

### BRIEF DESCRIPTION OF THE DRAWINGS

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings, in which:

FIG. 1 depicts a perspective view of a fixture according to one or more embodiments of the present disclosure;

FIG. 2 depicts a perspective view of a substrate according to one or more embodiments of the present disclosure;

FIG. 3 depicts a perspective view of a substrate according to one or more embodiments of the present disclosure;

FIG. 4 depicts a perspective view of a fixture with a substrate within the fixture according to one or more embodiments of the present disclosure;

FIG. 5 depicts a perspective view of a fixture with a substrate within the fixture according to one or more embodiments of the present disclosure;

FIG. 6 depicts a cross-sectional side view of a system including a fixture and a substrate according to one or more embodiments of the present disclosure;

FIG. 7 depicts a cross-sectional side view of a system including a fixture and a substrate during the deposition process according to one or more embodiments of the present disclosure;

FIG. 8 depicts a cross-sectional side view of a system including a fixture and a substrate during the deposition process according to one or more embodiments of the present disclosure.

FIG. 9 depicts a side view of a substrate with a coating on it according to one or more embodiments of the present disclosure.

FIG. 10 depicts a cross-sectional side view of a fixture according to one or more embodiments of the present disclosure.

FIG. 11 depicts a cross-sectional side view of a system including a fixture and a substrate during the deposition process according to one or more embodiments of the present disclosure;

FIG. 12 depicts a cross-sectional side view of a system including a fixture and a substrate according to one or more embodiments of the present disclosure;

FIG. 13 depicts a front view of a fixture and substrate from the view of the opening or aperture according to one or more embodiments of the present disclosure;

FIG. 14 depicts a front view of a fixture and substrate from the view of the opening or aperture according to one or more embodiments of the present disclosure;

FIG. 15 depicts a cross-sectional side view of a system including a fixture and a substrate according to one or more embodiments of the present disclosure;

FIG. 16 depicts a cross-sectional side view of a system including a fixture and a substrate after the deposition process according to one or more embodiments of the present disclosure;

FIG. 17 depicts a side view of a substrate with a coating on it according to one or more embodiments of the present disclosure;

FIG. 18 depicts a fixture according to one or more embodiments of the present disclosure.

Throughout the description, similar reference numbers may be used to identify similar elements.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

The expression “configured to” as used herein may be used interchangeably with “suitable for,” “having the capacity to,” “designed to,” “adapted to,” “made to,” or “capable of” according to a context. The term “configured” does not necessarily mean “specifically designed to” at a hardware level. Instead, the expression “apparatus configured to . . . ” may mean that the apparatus is “capable of . . . ” along with other devices or parts in a certain context.

The terms “part”, “component”, “device”, or “item” may be used interchangeably. These terms are meant to include substrates, printed circuit boards, and any other item that is or can be coated.

While many embodiments are described herein, at least some of the described embodiments facilitate easier loading, more conformality, and better uniformity of deposition. One example of a use case for embodiments of the present invention includes printed circuit boards for electronic devices. These are coated with a polymer or other protective coating. One class of coating material that has proven well suited to chemical vapor deposition on a part such as a printed circuit board is Parylene. Parylene offers excellent waterproof and other protective qualities.

Within this context, improved coating techniques are needed to perform the coating of substrates or other parts in an efficient manner, capable of mass processing, and with little waste of material or processing time.

Embodiments described herein include a fixture opening, crevice, or aperture that allows for a repeatable and consistent gradient coating on a substrate. A gradient coating in this context is a coating with a varying level of thickness across the substrate. As an example, the substrate would have a thicker coating that transitions to a thinner coating. This may be accomplished through the fixtures described herein. The use of restricted flow through a single opening on the fixture allows for the deposition of material to be greater near the opening compared to deep within the fixture. The use of the fixtures allows for a repeatable coating as the fixture will provide a consistent restriction of flow of the material to be deposited.

Chemical vapor deposition (CVD) coatings, such as the Parylenes, have various levels of “crevice penetration”, “penetration depth”, or “throwing distance” defined by the material [chemical structure of the coating's reactive monomer, that monomer's sticking coefficient, etc.], the process parameters [deposition rate, base pressure, chamber temperature, target thickness, etc.], and substrate [aperture or opening size into the area to be coated, the internal volume and geometry of the area to be coating, etc.].

Taking the coating material and deposition process into account, then well-defined and controlled apertures and internal volumes have provided the desired coating gradients for applications related to a variety of engineering and scientific applications, such as optical spectroscopy.

Fixtures have been developed to provide controlled thickness gradients over defined areas, such as silicon wafers, for single-sided and double-sided coating applications.

An iterative fixture design and evaluation process has been developed that includes computer-aided design (CAD), computer-aided manufacturing (CAM) using a fused filament fabrication (FFF) 3D printer with poly(lactic acid) (PLA) thermoplastic polymer, post-print processing to remove any extraneous material from the fixtures, loading silicon wafers into the fixtures, minimally securing the wafer into place, coating with Parylene, removing the wafers from the fixtures, and measuring the coating thickness with either spectral reflectance or spectroscopic ellipsometry, depending on the thickness range of the gradient.

The thickness measurements on the wafer dictate whether the fixture needs to be modified via CAD and then the process repeats until the desired thickness gradient has been achieved. Types of fixture modifications may include vertical or horizontal orientation of the wafer to sample rack and/or vapor flow, size of the opening, gap size from fixture walls to sample, and degree of gap size restriction from opening to endpoints.

Other means of fixture manufacturing are possible and can include different thermoplastic polymers via fused filament fabrication (FFF) printing, such as ABS, PETG, PVB, PC, nylon, etc.; light-cured polymeric materials via stereolithography (SLA) 3D printing; selective laser sintering (SLS) powder-based 3D printing; as well as more conventional methods, such as injection molding, casting, etc.

The crevice penetration and/or throwing distance behavior of the various Parylenes are known to those in the field. Well-defined thickness gradient coatings were requested for sensor die, which were on the order of 17 mm in length and width, for which the coating was needed for its optical properties and not necessarily the chemical and corrosion barrier properties.

Based on historical knowledge of the coating materials and the physics of the deposition, we've developed these coating fixtures. By 3D printing the fixtures, we've been able to perform both rapid prototyping and iterative design feedback changes to achieve the specified goals.

One of the main benefits of Parylene coatings is that they provide a conformal and uniform thickness across all exposed surfaces of a product or substrate. The specific thickness gradients that were provided as targets were achieved through knowledge of the coating behavior within tight volumes and then exploiting that behavior through careful design and experimentation.

Other means of fixture fabrication are noted earlier. The principles of these coating fixtures apply across the Parylenes and may require additional tuning to account for different Parylene's throwing distance. These fixtures and design principles may also be useful for different coating materials and deposition processes.

Key aspects of the design that can be tuned or added, including but not limited to:

Opening size and dimensions relative to parts;

A simple box, sloped, stepped, and curved profile from opening to depth

Backstop shape and distance from part edge to control eddy currents and thickness uniformity;

Fixturing method for holding parts without blemishing coating in an optically sensitive zone.

Other means of fixture fabrication are noted earlier. While the thickness gradients described and developed through the processes described are meant for imaging and spectroscopic analysis applications, the principles of extremely tight control of coating thickness may be useful in further device miniaturization and allowing for coated components to be assembled into very tight constraints of a higher level assembly or housing.

Various methods of use and manufacture are contemplated herein as well. Some embodiments utilize a fixture with a small opening on one end of the fixture to allow egress of the material that will be deposited on the substrate. The sizing and the shape of the interior of the fixture may correspond to the substrate or electronic device that is placed within the fixture. The interior shape of the fixture may start larger and decrease to allow less space next to the substrate the farther in from the opening one gets. Some embodiments of the fixture allow for a repeatable coating because of the particular shape of the fixture.

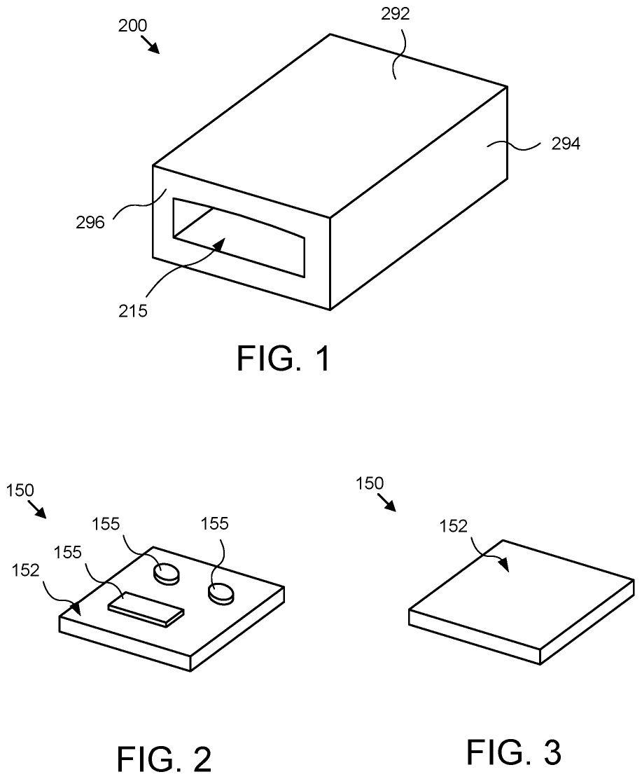

Referring now to FIG. 1, a perspective view of a fixture 200 is depicted. Although the fixture 200 is shown and described with certain components, modules and functionality, other embodiments of the fixture 200 may include fewer or more components or modules to implement less or more functionality.

The fixture 200 is configured to house a substrate during a deposition process. In this context, the deposition process is a chemical vapor deposition processes (CVD) that is used to deposit a material on the substrate. FIG. 1 depicts only the fixture 200 without a substrate inside.

The fixture 200 is configured to house the substrate during deposition of the coating. The fixture 200 is configured to surround the substrate on all sides of the substrate except for a single side. The fixture 200 includes an opening or aperture 215. This single aperture 215 is the area of access for the coating material. The coating material must egress into the fixture from the aperture 215 for deposition to occur. For simplicity of description, the fixture 200 includes a top or top side 292, a side 294, a front side 296, a rear side opposite the front side (not visible), a bottom side opposite the top side 292, and another side opposite the side 294.

Referring to FIG. 2, a perspective view of a substrate 150 is depicted. Although the substrate 150 is shown and described with certain components, modules and functionality, other embodiments of the substrate 150 may include fewer or more components or modules to implement less or more functionality.

In the illustrated embodiment, the substrate 150 is a printed circuit board with various electronic components 155. The substrate 150 is the item, part, component, or device that is to be coated. As such, the substrate 150 may have a simple shape and design or may be complicated in shape and design.

Referring now to FIG. 3, a perspective view of an embodiment of a substrate 150 is shown. As is depicted, the substrate 150 is a simple wafer with a flat surface. Each of the two substrates of FIGS. 2 and 3 have a major top side 152 that is to be deposited with a coating. In embodiments where two major sides are to be deposited with a coating, the major bottom side (not visible) is on the opposite side of the substrate.

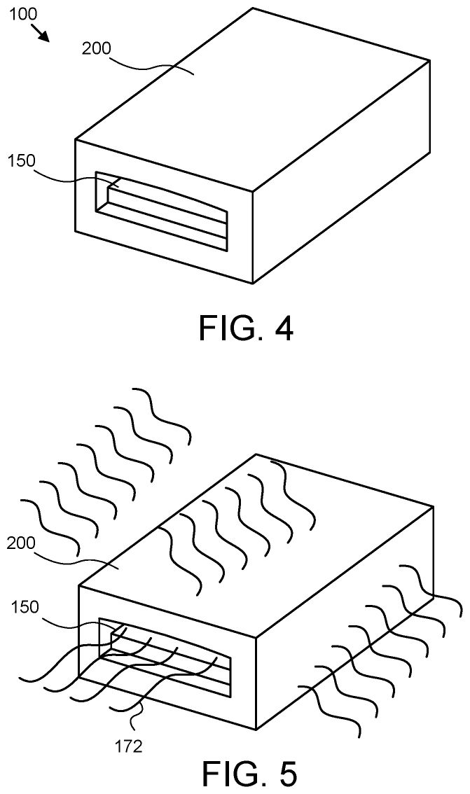

Referring now to FIG. 4, a perspective view of a fixture 200 with a substrate 150 within the fixture is depicted. As can be seen through the opening or aperture of the fixture 200, the substrate 150 is seated in the fixture 200. The fixture 200 has a small opening located at the front of the fixture allowing for the egress of material into the fixture and allowing chemical vapor deposition on the major top side of the substrate. Because the material enters at the aperture and there is minimal gap between the substrate 150 and the fixture 200 above the major top side of the substrate, the coating is deposited with a gradient. That is, generally, the coating will be thicker the closer to the aperture. Deeper within the fixture, the coating will be thinner. Coating thickness is dependent upon many variables including deposition time. With sufficient deposition time, the coating may achieve a full thickness at the back (deep within the fixture), but with any abbreviated deposition time, the coating will have a gradient of thickness, which is depicted in later figures.

Referring now to FIG. 5, a perspective view of a fixture 200 with a substrate 150 within the fixture is depicted. Also depicted in this figure are the chemical vapors 172 that are working to be deposited within a deposition chamber (not depicted). The chemical vapors or coating material vapors 172 are blocked in all directions except through the aperture or opening at the front of the fixture 200. Deposition of the coating onto the substrate 150 can only occur as the materials enter through the aperture and are deposited on the substrate 150.

As described earlier, this deposition creates a gradient coating or a thickness gradient coating on the major top side of the substrate 150 with a thicker coating at the opening or aperture and decreasing in thickness the deeper within the fixture one goes.

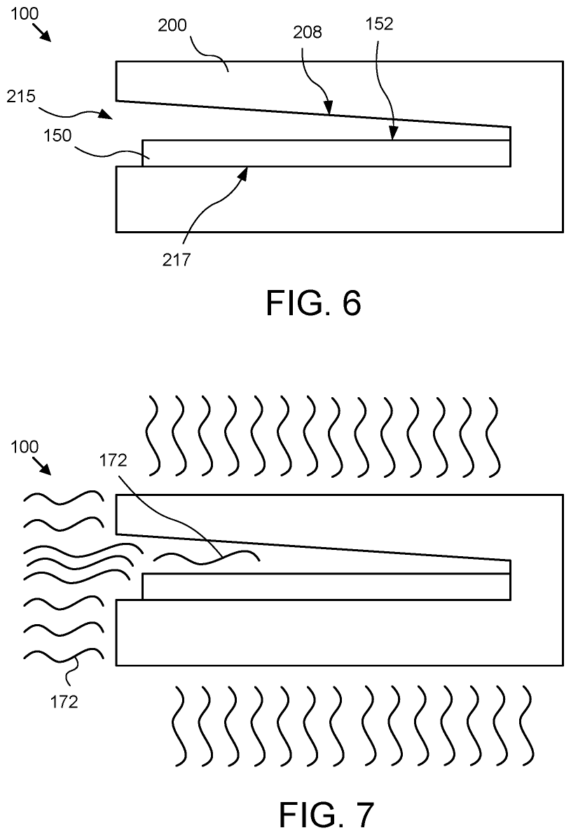

Referring now to FIG. 6, a cross-sectional side view of a system 100 including a fixture 200 and a substrate 150 is depicted. This system is one example of many possible systems including a fixture 200 and substrate 150. For clarity, the sides of the fixture 200 are removed or not visible in this cross-sectional view to more easily see the profile of the cavity within the fixture 200 and the profile of the substrate 150. As can be seen, in this illustrated embodiment, the substrate 150 is merely a simple flat wafer with a rectangular cross section. The fixture 200 shows the opening or aperture 215 at the front side of the fixture 200. The cavity within the fixture includes a bottom seat surface 217. This is the surface that the substrate 150 sits on within the fixture 200. For a simple wafer like what is depicted in the illustrated embodiment, this is just a flat surface that is approximately the same size as the wafer. Also bounding the cavity of the fixture is what is termed a lid surface 208. The lid surface 208 is configured to be raised above the major top side 152 of the substrate. As can be seen, there is an air gap between the lid surface 208 and the major top side 152 of the substrate.

Referring now to FIG. 7, a cross-sectional side view of a system 100 including a fixture 200 and a substrate 150 is depicted during the deposition process. For clarity, the sides of the fixture 200 are removed or not visible in this cross-sectional view to more easily see the profile of the cavity within the fixture 200 and the profile of the substrate 150. During the deposition process, the fixture 200 acts as a shield blocking the coating material vapors 172 in all directions except for through the opening or aperture of the fixture and into the cavity and the air gap above the major top side of the substrate. As shown, the coating material vapors 172 are ingressing into the fixture through the opening or aperture and are moving to coat the major top side of the substrate.

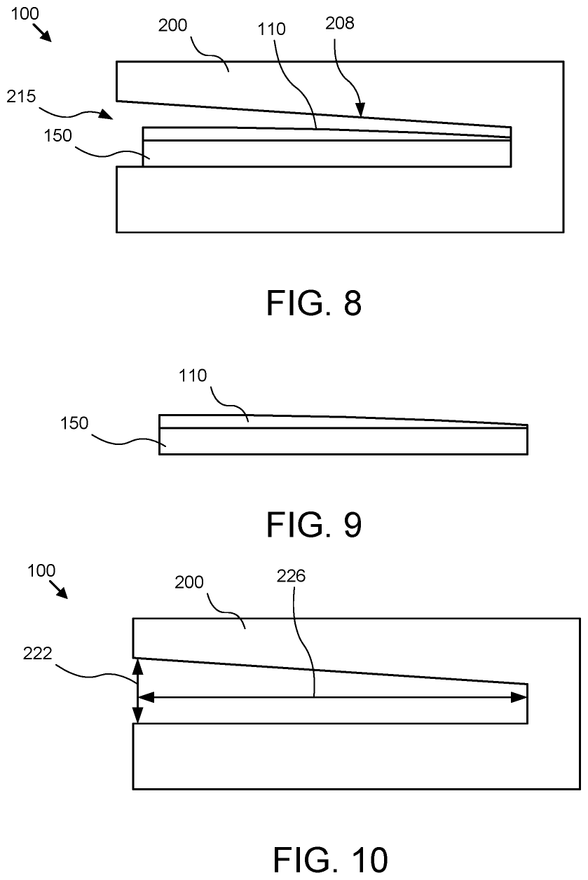

Referring now to FIG. 8, a cross-sectional side view of a system 100 including a fixture 200 and a substrate 150 is depicted during the deposition process. For clarity, the sides of the fixture 200 are removed or not visible in this cross-sectional view to more easily see the profile of the cavity within the fixture 200 and the profile of the substrate 150 and the profile of the coating 110. This is after the deposition process has been completed. As can be seen, the coating 110 has a greater thickness the closer to the opening or aperture 215. The coating 110 is a gradient coating. The fixture 200, with a relatively small opening or aperture relative to the depth or distance to the back of the cavity allows for a somewhat restricted flow of the coating material vapors 172. It is more difficult for the coating material vapors 172 to make it to the back of the cavity. The relatively small gap between the lid surface 208 and the major top side 152 restricts the flow of the vapors during the deposition process.

Now, as can be seen, in the embodiments depicted so far, the lid surface 208 may vary the gap distance between the substrate 150 and the fixture 200. This surface profile may be utilized to further restrict flow and allows for the repeatable deposition of a coating. That is, along with only having a single access point for the coating material, the air gap distance may also vary to further restrict the thickness of the resulting coating.

In the illustrated embodiment, the lid surface 208 is tapered or sloped. That is, the cavity within the fixture 200 is thicker at the opening or aperture 215 and gets thinner at the back of the cavity. The shape and contour of the lid surface 208 may be changed to create a particular coating profile.

Referring now to FIG. 9, a side view of a substrate 150 with a coating 110 on it is depicted. As can be seen, the coating is a gradient coating or has a gradient of its thickness.

Referring now to FIG. 10, a cross-sectional side view of a fixture 200 is depicted. For clarity, the sides of the fixture 200 are removed or not visible in this cross-sectional view to more easily see the profile of the cavity within the fixture 200. The illustrated embodiment is shown to more easily show the relative sizes of the crevice opening thickness 222 and the cavity depth 226. The arrows represent these particular measurements. Although not depicted as actual measured distances in the illustrated embodiment, the crevice opening thickness 222 is much smaller than the cavity depth 226. This makes sense because if the crevice opening thickness 222 was larger than the cavity depth 226, then the fixture 200 would not restrict the flow of the coating material during deposition. Embodiments of the invention described herein work to produce repeatable coating profiles because the fixture 200 surrounds the substrate 150 on all sides except for the front. And the fixture 200 has a lid surface that is close enough to the substrate relative to the size of the opening.

The ratio of these two distances can be varied depending on the needs of the coating profile but the cavity depth 226 must be greater than the crevice opening thickness 222.

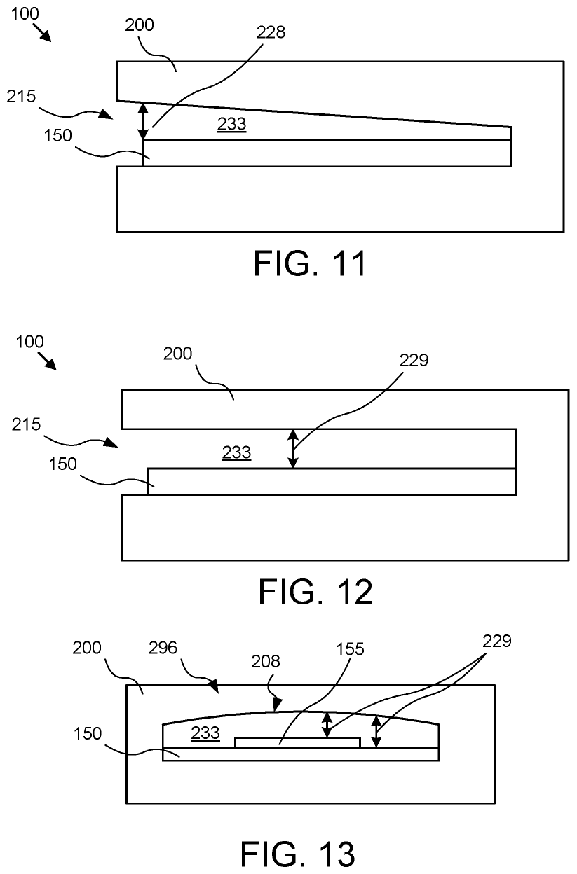

Referring now to FIG. 11, a cross-sectional side view of a system 100 including a fixture 200 and a substrate 150 is depicted during the deposition process. For clarity, the sides of the fixture 200 are removed or not visible in this cross-sectional view to more easily see the profile of the cavity 233 within the fixture 200 and the profile of the substrate 150. This Figure introduces another distance that is important, a gap opening distance 228. In fact, the gap opening distance 228 is likely more important than the crevice opening thickness 222. This can be visualized by thinking of an extremely thick substrate. With an extremely thick substrate, the crevice opening thickness 222 may be large, but the fixture should be made to have a relatively small gap opening distance 228. The ingress of the coating material is restricted by the distance between the major top side of the substrate and the lid surface 208. That is why the gap opening distance 228, which measures the distance between the lid surface 208 and the major top side 152 of the substrate, is more important than the crevice opening thickness 222.

The ratio of the gap opening distance 228 and the cavity depth 226 can be varied depending on the needs of the coating profile but the cavity depth 226 must be greater than the gap opening distance 228. In many cases, the cavity depth 226 should be at least four times greater than gap opening distance 228.

Referring now to FIG. 12, a cross-sectional side view of a system 100 including a fixture 200 and a substrate 150 is depicted. For clarity, the sides of the fixture 200 are removed or not visible in this cross-sectional view to more easily see the profile of the cavity 233 within the fixture 200 and the profile of the substrate 150. In this illustrated embodiment, the lid surface 208 matches or mirrors the major top surface of the substrate 150. That is, the gap distance 229 is uniform across the entire substrate. While it is easy to depict with a flat substrate, embodiments of the fixture 200 may include a lid surface 208 that matches an irregularly shaped substrate. As was described earlier, the distance between the substrate and the lid surface is what functions to restrict the movement of the coating material during the deposition process.

Referring now to FIG. 13, a front view of a fixture 200 and substrate 150 from the view of the opening or aperture is shown. As can be seen, the front side 296 of the fixture 200 is shown. The substrate 150 includes an electronic component 155. The substrate 150 is seated within the cavity 233 of the fixture 200. Also shown is the gap distance 229, or the distance between the major top side of the substrate and the lid surface 208. This front view shows that the lid surface may be contoured from side to side as well. In many embodiments, the lid surface 208 may be contoured to produce a uniform gap distance 229 from side to side. The illustrated embodiment, shows an irregularly shaped substrate with the electronic component and as such with a lid surface 208 that tapers on each side.

As previously discussed, the lid surface can be made to the specification for the device or substrate that is needed to be coated. The fixture is configured to allow for predictable ingress of coating material into the cavity and thus a predictable and repeatable coating gradient profile. As the shape and size of the substrate is limitless, the important features of the fixture are the low relative height of the cavity that can restrict flow of the coating material into a deep cavity.

Throughout this description, for clarity and ease of discussion, the embodiments have been single sided depositions. That is, the deposition of the coating material is on a single side of the substrate. The features and discussion from above can also be applied to substrates that need a gradient coating on both sides of a substrate.

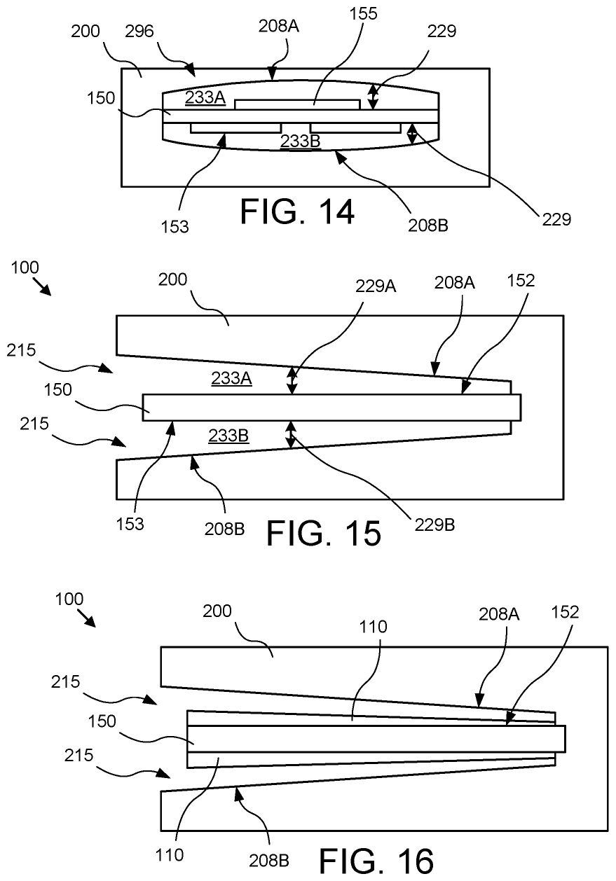

Referring now to FIG. 14, a front view of a fixture 200 and substrate 150 from the view of the opening or aperture is shown. As can be seen, the front side 296 of the fixture 200 is shown. The substrate 150 includes an electronic component 155 on each side of the substrate 150. The substrate 150 is no longer seated within the cavity 233 of the fixture 200 but is suspended (held in place at the back of the cavity so that there is a cavity space 233A above the substrate and a cavity space 233B below the substrate. Also shown is the gap distance 229, or the distance between the major top side of the substrate and the lid surface 208A. The bottom surface of the cavity is also referred to as a lid surface 208B and the gap distance 229 between the major bottom surface 153 of the substrate and the bottom lid surface 208B is shown. This front view shows that the lid surface may be contoured from side to side as well.

The double sided fixture may be more easily envisioned using FIG. 15 which is another embodiment. Referring now to FIG. 15, a cross-sectional side view of a system 100 including a fixture 200 and a substrate 150 is depicted. This system is one example of many possible systems including a fixture 200 and substrate 150. For clarity, the sides of the fixture 200 are removed or not visible in this cross-sectional view to more easily see the profile of the cavity within the fixture 200 and the profile of the substrate 150. As can be seen, in this illustrated embodiment, the substrate 150 is merely a simple flat wafer with a rectangular cross section. The fixture 200 shows the opening or aperture 215 at the front side of the fixture 200. The cavity within the fixture includes a top lid surface 208A and a bottom lid surface 208B. This substrate 150 is seated within the fixture 200 at the back of the cavity. The mechanism for holding the substrate is not described in detail but fixture may be rotated ninety degrees with the wafer or substrate seated at the back of the cavity.

For ease of discussion, the fixture of FIG. 15 is depicted similarly to those previously and the orientation convention is continued with top, bottom, front, and side. This should not be viewed as limiting but helpful for understanding.

Referring now to FIG. 16, a cross-sectional side view of a system 100 including a fixture 200 and a substrate 150 is depicted after the deposition process. For clarity, the sides of the fixture 200 are removed or not visible in this cross-sectional view to more easily see the profile of the cavity within the fixture 200 and the profile of the substrate 150 and the profile of the coating 110. This is after the deposition process has been completed. As can be seen, the coating 110 has a greater thickness the closer to the opening or aperture 215. The coating 110 is a gradient coating and is located on both the major top side and major bottom side of the substrate. The fixture 200, with a relatively small opening or aperture relative to the depth or distance to the back of the cavity allows for a somewhat restricted flow of the coating material vapors 172 (not shown). It is more difficult for the coating material vapors 172 to make it to the back of the cavity. The relatively small gap between the lid surfaces 208A, 208B and the major top side and major bottom side restricts the flow of the vapors during the deposition process.

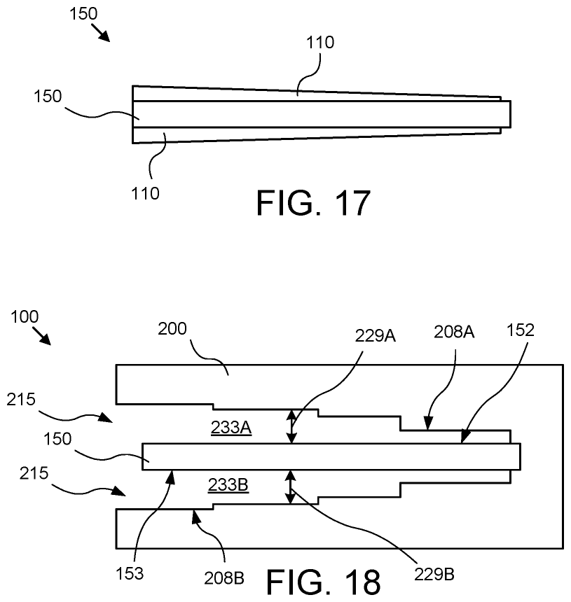

Referring now to FIG. 17, a side view of a substrate 150 with a coating 110 on it is depicted. As can be seen, the coating is a gradient coating or has a gradient of its thickness and is located on both major sides of the substrate 150.

Referring now to FIG. 18, another embodiment of a fixture 200 is depicted for illustrative purposes. As described above, the lid surface 208 of a fixture 200 may have differing contours. The illustrated embodiment depicts a stepped lid surface that steps down in thickness the deeper into the cavity one goes. Such a profile may allow for the creation of a unique coating gradient profile. This is depicted to illustrate that the lid surface contour may be unique to the needs of the coating. The gap distance 229A, 229B will still be much smaller than the cavity depth. The ratio of the gap distance to the cavity depth may be an order of magnitude lower for the gap distance as compared to the cavity depth in many embodiments.

The gap distance may also be dictated by the material to be deposited as different materials will accomplish different rates of ingress into the cavity.

While the coating material may be any material deposited by chemical vapor deposition, the above fixtures have been developed for the deposition of all types of Parylenes.

Not all shapes and contours of fixtures are depicted herein. Many different fixtures are shown in U.S. Provisional Application No. 63/406,883, the contents of which are incorporated by reference herein. Each of the Figures in the Provisional depicts various shapes and sizes for fixtures which may lead to different and particular results. The openings of the fixtures vary in size and shape allowing for a varied shape of the opening and a varied size relative to the substrate. The size of the gap between the substrate and the fixture may be determined through testing to find the appropriate gap size or gap distance that produces the best results. Such results will then be largely repeatable based on repeating the depositing pressure, deposition material, deposition temperature, deposition rate, deposition time and other known parameters for deposition. Each of these parameter can also be adjusted independently if needed.

In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

Although the operations of the method(s) or processes herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A fixture for depositing a gradient coating in a chemical vapor deposition chamber, the fixture comprising:
a single opening on a front side of the fixture, such that the fixture is configured to house a substrate during deposition of a coating and configured to surround the substrate on all sides of the substrate except for a single front side of the substrate, and wherein the fixture is configured to restrict egress of coating material to the substrate from all directions except through the single opening;
a cavity such that the fixture is configured to leave an air gap between a lid surface of the fixture and the major top side of the substrate, and
wherein a cavity depth, measured from the front side of the fixture to a back of the cavity, is greater than a gap opening distance, measured from the lid surface at the opening to the major top side of the substrate.

2. The fixture of claim 1, wherein the lid surface is contoured to match a shape of the major top surface.

3. The fixture of claim 1, wherein the substrate comprises a gradient coating with a first thickness at the opening and a second thickness at a rear of the cavity, wherein the first thickness is greater than the second thickness.

4. The fixture of claim 1, wherein the cavity depth is ten times greater than the gap opening distance.

5. The fixture of claim 1, wherein the cavity depth is one hundred times greater than the gap opening distance.

6. The fixture of claim 1, wherein the lid surface is graded or sloped such that a gap distance from the lid surface to the major top side decreases with depth into the cavity.

7. The fixture of claim 1, wherein the fixture is configured to leave a second air gap between a bottom lid surface of the fixture and a major bottom side of the substrate.

8. The fixture of claim 7, wherein the lid surface is contoured to match a shape of the major top surface and the bottom lid surface of the fixture is contoured to match a shape of a major bottom surface of the substrate.

9. A chemical vapor deposition coating system for depositing a gradient coating, the system comprising:
a substrate comprising a major top side, wherein the first major top side is to be deposited with a coating of a material via chemical vapor deposition; and
a fixture for the substrate, the fixture configured to house the substrate during deposition of the coating,
wherein the fixture is configured to surround the substrate on all sides of the substrate except for a single front side of the substrate and wherein the fixture comprises:
an opening on a front side of the fixture, and wherein the fixture is configured to restrict egress of the material to the substrate from all directions except through the opening; and
a cavity such that the fixture is configured to leave an air gap between a lid surface of the fixture and the major top side of the substrate,
and wherein a cavity depth, measured from the front side of the fixture to a back of the cavity, is greater than a gap opening distance, measured from the lid surface at the opening to the major top side of the substrate.

10. The chemical vapor deposition coating system of claim 9, wherein the lid surface is contoured to match a shape of the major top surface.

11. The chemical vapor deposition coating system of claim 9, wherein the substrate comprises a gradient coating with a first thickness at the opening and a second thickness at a rear of the cavity, wherein the first thickness is greater than the second thickness.

12. The chemical vapor deposition coating system of claim 9, wherein the cavity depth is ten times greater than the gap opening distance.

13. The chemical vapor deposition coating system of claim 9, wherein the cavity depth is one hundred times greater than the gap opening distance.

14. The chemical vapor deposition coating system of claim 9, wherein the lid surface is graded or sloped such that a gap distance from the lid surface to the major top side decreases with depth into the cavity.

15. The chemical vapor deposition coating system of claim 9, wherein the fixture is configured to leave a second air gap between a bottom lid surface of the fixture and a major bottom side of the substrate.

16. The chemical vapor deposition coating system of claim 15, wherein the lid surface is contoured to match a shape of the major top surface and the bottom lid surface of the fixture is contoured to match a shape of a major bottom surface of the substrate.

17. The chemical vapor deposition coating system of claim 15, wherein the substrate comprises a gradient coating with a first thickness at the opening and a second thickness at a rear of the cavity on the major top side, wherein the first thickness is greater than the second thickness, and wherein the substrate comprises a second gradient coating onto the major bottom side of the substrate.

18. The chemical vapor deposition coating system of claim 15, wherein the cavity depth is ten times greater than the gap opening distance.

19. The chemical vapor deposition coating system of claim 15, wherein the cavity depth is one hundred times greater than the gap opening distance.

20. The chemical vapor deposition coating system of claim 15, wherein the lid surface stepped surface such that a gap distance from the lid surface to the major top side decreases with depth into the cavity.
